(19) United States
(12) Patent Application Publication
(10) Pub. No.: US 2022/0039292 A1
(43) Pub. Date: Feb. 3, 2022

(54) SUB-MODULE COOLING DEVICE OF POWER TRANSMISSION SYSTEM

(71) Applicant: HYOSUNG HEAVY INDUSTRIES CORPORATION, Seoul (KR)

(72) Inventors: Chang Woo HAN, Goyang-si, Gyeonggi-do (KR); Seung Boong JEONG, Seoul (KR)

(21) Appl. No.: 17/299,661

(22) PCT Filed: Nov. 18, 2019
(86) PCT No.: PCT/KR2019/015786

§ 371 Date: Jun. 3, 2021

(30) Foreign Application Priority Data
Dec. 6, 2018 (KR) 10-2018-0155927

(51) Int. Cl. H05K 7/20

(52) U.S. Cl. CPC H05K 7/20336; H05K 7/209; H05K 7/20936; H05K 7/20909; H05K 7/20145

(57) ABSTRACT

A sub-module cooling device of a power transmission system is proposed. Sub-modules may be arranged in a row on each of multiple layers of a frame. Heat generated by the sub-modules may be transferred to a duct through heat pipes, and the heat transferred through the heat pipes may be discharged to the outside while air coming out from an air conditioner passes through the duct. When the heat generated by the sub-modules is discharged in this manner, a cooling fan may not be required to be installed in each of the sub-modules. Air may be flown by the operation of the air conditioner and may absorb the heat generated by the sub-modules and discharge the heat to the outside.

### TECHNICAL FIELD

The present disclosure relates generally to a sub-module cooling device of a power transmission system. More particularly, the present disclosure relates to a sub-module cooling device of a power transmission system in which heat generated by sub-modules is discharged to the outside by using air supplied by a cooling air supply source.

### BACKGROUND ART

A high voltage direct current system (an HVDC system) supplies power by converting DC power to AC power at a power receiving point after converting the AC power produced in a power plant to the DC power and transmitting the DC power to the power receiving point. Such an HVDC system is a power transmission method that has good transmission efficiency due to less loss than an AC transmission method and is advantageous for long-distance power transmission due to improved stability through system separation and low induction interference.

In the HVDC system, multiple sub-modules are installed in a frame having height of several meters and being multiple layered. For example, at least two layers are formed in one frame, and multiple sub-modules are installed in a row on each of the layers. The sub-modules generate much heat during operation. Accordingly, much research is being conducted on a structure for discharging heat generated by the sub-modules to the outside.

In addition, in a power transmission system, there is a flexible alternative current transmission system (an FACT system) using power semiconductors. In the flexible alternative current transmission system, control technology using semiconductor switching elements for power is introduced to the AC transmission line, the AC system's flexibility was increased, thereby increasing flexibility of the AC system and improving characteristics of the AC system due to supplementation of shortcomings thereof. Sub-modules similar to the sub-modules used in the high voltage direct current system are used even in the flexible alternative current transmission system.

In a conventional technology, to discharge heat generated by the sub-modules to the outside, cooling water is used. However, when leakage of the cooling water occurs during the use of the cooling water, a short circuit or corrosion in the sub-modules is caused.

In order to solve the problem of the water cooling, it is recommended that air is used as a medium for heat dissipation. However, when air is used, it is difficult to supply the air to the inside of each of the sub-modules, and a blower fan is required to be used for each of the sub-modules. However, even the blower fan is a heat source, so when multiple blower fans are used, much heat is generated as a whole, and much effort is required for maintenance of the blower fans.

### DISCLOSURE

### Technical Problem

The present disclosure has been made keeping in mind the above problems occurring in the prior art, and the present disclosure is intended to propose a sub-module cooling device in which heat generated by sub-modules of a power transmission system such as a high voltage direct current system or a flexible alternative current transmission system may be discharged to the outside by using air.

In addition, the present disclosure is intended to propose a sub-module cooling device in which air used to cool the sub-modules of a power transmission system may be supplied by an air conditioner.

### Technical Solution

In order to accomplish the above objectives, according to an aspect of the present disclosure, a sub-module cooling device of a power transmission system of the present disclosure includes: a frame having multiple sub-modules located on each of divided multiple layers of the frame, the sub-modules being arranged in a row on the layer; a heat sink provided at each of the sub-modules and configured to receive heat from a heating part of the sub-module; a heat pipe configured to receive the heat from the heat sink at an evaporation part provided at a first end part thereof and to transmit the heat to a condensation part provided at a second end part thereof; a duct receiving the condensation part of the heat pipe therein; and an air conditioner configured to transmit air having a predetermined temperature to the duct.

In the duct, the air may flow in a vertical direction.

Multiple heat radiating fins may be provided at the condensation part of the heat pipe located in the duct.

The frame in which the sub-modules are installed may be arranged in a separate installation space.

Air having a preset temperature may be supplied to the installation space by an air conditioner.

Instead of the one heat pipe, multiple heat pipes may be provided between the sub-module and the duct and may be connected to each other by a connecting heat sink such that heat generated by the heat sink of the sub-module is transmitted to the duct.

The multiple heat pipes inclining in directions of gravity may be provided between the heat sink of the sub-module and the multiple heat radiating fins.

An insulator may be provided at the heat pipe.

An inside of the duct may be divided into multiple paths, and the air coming out of the air conditioner may flow to each of the paths, wherein heat pipes divided as many as the number of the paths may be arranged in the paths, respectively.

Heat pipes connected to sub-modules arranged on one layer may be arranged in one path sectioned in the duct.

### Advantageous Effects

The sub-module cooling device of a power transmission system according to the present disclosure may have the following effects.

In the cooling device of the present disclosure, a heat pipe may be installed between each of the multiple sub-modules and a duct, and heat generated by the sub-modules may be transmitted to air flowing in the duct through the heat pipe, thereby efficiently discharging the heat generated by the multiple sub-modules to the outside by transmitting the heat to the air flowing in the duct.

Particularly, air flowing in the duct may be supplied by an air conditioner, thereby making the use of a separate air blower in each of the sub-modules unnecessary and minimizing effort for maintenance thereof.

In addition, condensation parts of the heat pipes located in the duct may be located at different positions according to the installation heights of the sub-modules, and the inside of the duct may be divided such that air supplied by the air conditioner is supplied directly to the condensation parts located at different positions, so heat dissipation may be efficiently performed even in a condensation part of the heat pipe located at a lower flow part of air in the duct, thereby uniformly performing heat dissipation of the entirety of the sub-modules without being biased.

### DESCRIPTION OF DRAWINGS

FIG. 1 is a view illustrating the configuration of a sub-module cooling device of a power transmission system according to an exemplary embodiment of the present disclosure.

FIG. 2 is a view illustrating the entire configuration of the cooling device according to the embodiment of the present disclosure.

FIG. 3 is a view illustrating the entire configuration of a cooling device according to another embodiment of the present disclosure.

FIG. 4 is a view illustrating a modified example in which a duct is divided in the cooling device according to each of the embodiments of the present disclosure.

FIG. 5 is a view illustrating the operation of the cooling device illustrated in FIG. 2.

FIG. 6 is a view illustrating the operation of the cooling device illustrated in FIG. 3.

### MODE FOR INVENTION

Hereinafter, some embodiments of the present disclosure will be described in detail through exemplary drawings. In adding reference numerals to components of each drawing, it should be noted that the same components have the same numerals when possible even if they are indicated on different drawings. In addition, in describing the embodiments of the present disclosure, when it is determined that a detailed description of a related known configuration or function interferes with the understanding of the embodiments of the present disclosure, the detailed description thereof will be omitted.

In addition, in describing the components according to the embodiments of the present disclosure, terms such as first, second, A, B, (a), and (b) may be used. These terms are only for distinguishing the components from other components, and the nature, order, or order of the components is not limited by the terms. When a component is described as being “connected” or “coupled” to another component, the component may be directly connected or coupled to the another component. However, it should be understood that still another component may be “connected” or “coupled” to each component therebetween. In this specification, for convenience, a sub-module cooling device of a power transmission system according to the present disclosure is applied to the sub-modules of an HVDC system as an example.

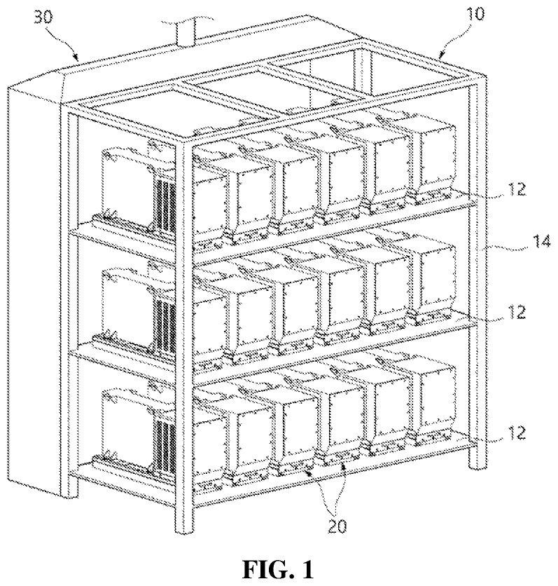

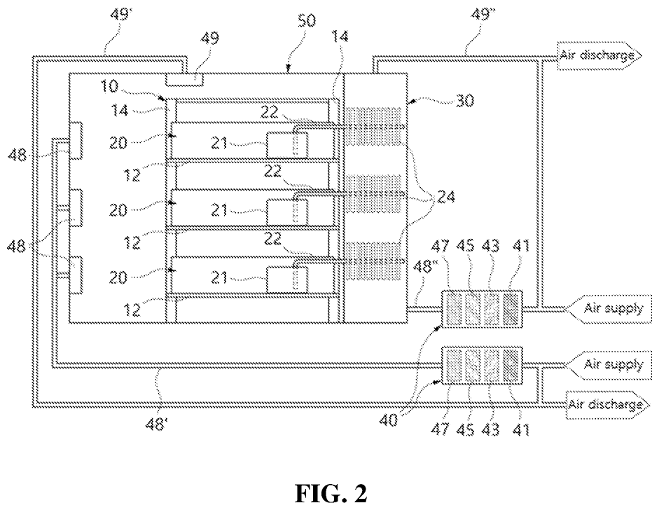

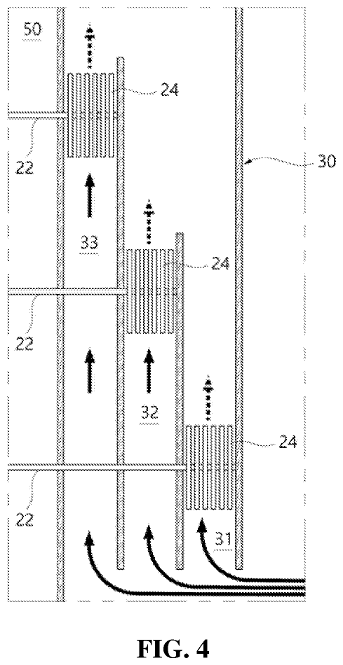

In FIG. 1, sub-modules 20 used in a high voltage direct current system (the HVDC system) are illustrated to be installed in a frame 10. In the frame 10, the dividing plates 12 constituting multiple layers may be provided, and columns 14 may be provided by vertically standing to support the dividing plates 12. The sub-modules 20 may be installed in a row on each of the dividing plates 12. A duct 30 may be installed at a side surface of the frame 10. Air supplied by an air conditioner 40 may flow through the duct 30. As illustrated in FIG. 2 or 4, the sub-modules 20 installed in the frame 10 may include multiple sub-modules located in an installation space 50 having predetermined divided sections.

Many parts that generate heat during operation may be provided in each of the sub-modules 20. A heat sink 21 may be provided at each of these many parts such that the generated heat is transmitted to the heat sink 21. The heat sink 21 may be made of metal with good thermal conductivity. The heat sink 21 may include several heat sinks and several heating parts may be in contact with one heat sink.

A first end of the heat pipe 22 may be in contact with the heat sink 21. The heat pipe 22 may be made of metal with good thermal conductivity. The heat pipe 22 may include an insulator to have insulation strength against the sub-module 20. Fluid that can be changed between liquid and gas phases may be filled in the heat pipe 22. When heat is applied to a first end part of the heat pipe 22, the fluid may be evaporated and have heat energy, and the evaporated fluid may flow to an end part opposite to the first end part and the heat is dissipated by air flowing in the duct. The air may pass through the inside of the duct and may return to an initial position thereof. Accordingly, the heat pipe 22 may receive heat at a first end part thereof and may discharge the heat to the outside through a second end part thereof. Accordingly, when the second end part of the heat pipe 22 is provided inside the duct 30, relative low temperature air passing through the duct may be heat-exchanged with the discharged heat such that the heat is transmitted to the air. Multiple heat radiating fins 24 may be provided at the outer surface of the second end part of the heat pipe 22 installed in the duct 30.

The air conditioner 40 may generate air having a predetermined temperature and transmit the air to the duct 30 and/or the installation space 50. As for the approximate configuration of the air conditioner 40, the air conditioner 40 may have a filter part 41 therein such that the filter part 41 filters foreign matter contained in the air. To set the temperature of the air passing through the filter part 41, a heating part 43 and a cooling part 45 may be sequentially installed. The heating part 43 and the cooling part 45 may be selectively used to supply heat to the air or take away heat from the air so as to bring the air to a desired temperature. A blowing part 47 may be provided at a position at which the air passes the cooling part 45 such that the air is transmitted to the duct 30. The blowing part 47 may allow air coming out from the air conditioner to be discharged to the outside through the duct 30 or may allow the air to flow back to the air conditioner through the duct 30.

Meanwhile, to set the temperature of the installation space 50, a separate air conditioner 40 may be used. Of course, one air conditioner 40 may be used to transmit air to each of the duct 30 and the installation space 50. In this case, air having different temperatures may be required to be transmitted to the duct 30 and the installation space 50, respectively. In this case, a device which can separately control temperatures may be provided.

An air supply diffuser 48 may be provided in the installation space 50, and air coming out from a separate air conditioner 40 may be transmitted to the air supply diffuser 48 through the air supply duct 48′. An air exhaust diffuser 49 may also be provided in the installation space 50. The air exhaust diffuser 49 may function to transmit air present in the installation space 50 to the separate air conditioner 40 or to the outside.

Here, the air conditioner 40 may be used by being separately manufactured for the cooling device of the present disclosure. However, the air conditioner 40 may be used for air conditioning in a building having the installation space 50. That is, the air conditioner 40 for air conditioning in a building may transmit a predetermined amount of air to the duct 30 and may discharge heat generated by the sub-module 20 to the outside.

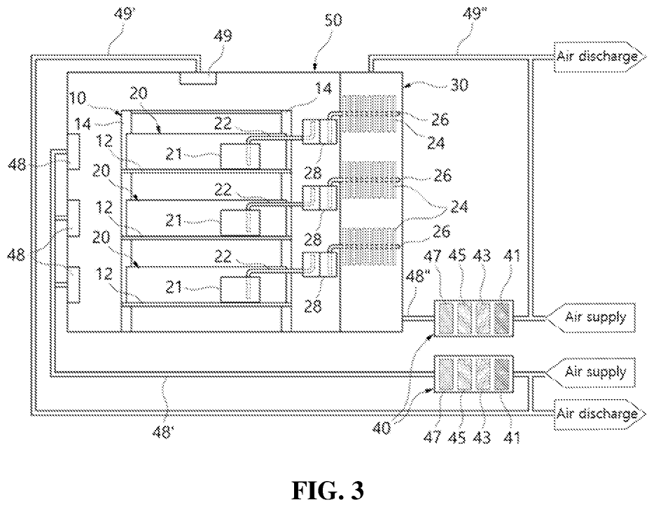

Another embodiment of the sub-module cooling device of the present disclosure is illustrated in FIG. 3. In the embodiment illustrated in FIG. 3, a first heat pipe 22 may not be directly introduced into the duct 30, and a second heat pipe 26 may be introduced into the duct 30. A connecting heat sink 28 may be provided between the first heat pipe 22 and the second heat pipe 26. A condensation part of the first heat pipe 22 which is a second end part thereof may be in contact with a first surface of the connecting heat sink 28 and an evaporation part of the second heat pipe 26 may be in contact with a second surface of the connecting heat sink 28. The connecting heat sink 28 may be mounted to a side of the duct 30 or the frame 10.

Accordingly, the first heat pipe 22 and the second heat pipe 26 may be used when a distance between the sub-module 20 and a wall of the installation space 50 or a distance between the sub-module 20 and the duct 30 is required to be at least a predetermined distance.

In FIG. 4, the inner configuration of the duct 30 is illustrated by being modified. Here, the inside of the duct 30 may be divided into several paths 31, 32, and 33. That is, the inside of the duct 30 may be divided into a first path 31, a second path 32, and a third path 33, and the second end part of the heat pipe 22 or 26 connected to the sub-module 20 installed on each different layer may be located in each of these paths 31, 32, and 33.

Relative to the drawing, the first path 31 may be on the far right, the second path 32 may be in the middle, and the third path 33 may be on the far left. A heat pipe 22 or 26, a second end part of which is installed in the first path 31, may pass transversely through the second path 32 and the third path 33. Accordingly, the second end part at which the heat radiating fins 24 are located may be located in the first path 31. The parts of the heat pipe passing through the second path 32 and the third path 33 may be exposed thereto, but may be wrapped with insulators so as to avoid heat transmission. A heat pipe 22, a second end part of which is installed in the second path 32, may pass transversely through the third path 33.

Accordingly, the second end part of each heat pipe 22 or 26 may be located in multiple paths, that is, inside the duct 30 divided into the first, second, and third paths 31, 32, and 33, so air having a temperature at the time at which the air comes out from the air conditioner 40 may be heat-exchanged with the heat radiating fins 24 of each heat pipe 22 or 26 by being in contact therewith. Accordingly, difference of heat dissipation between the sub-modules 20 installed on different layers may not occur. That is, heat generated by each of the sub-modules may almost uniformly be discharged to the outside 20.

In FIG. 4, the duct 30 is divided into the multiple paths 31, 32, and 33 such that the end parts thereof have different heights. However, the duct 30 may be divided into multiple paths formed in directions of large widths. In this case, the first heat pipe 22 may be introduced to one side from the sub-module 20 located at each layer and may be introduced into the duct 30. That is, the first heat pipe 22 of the sub-module 20 located at each layer may be configured to be introduced to the position of each of the divided paths 31, 32, and 33 and to be introduced into the duct 30.

Hereinafter, the operation of the sub-module cooling device of a power transmission system having the above-described configuration according to the present disclosure will be described in detail.

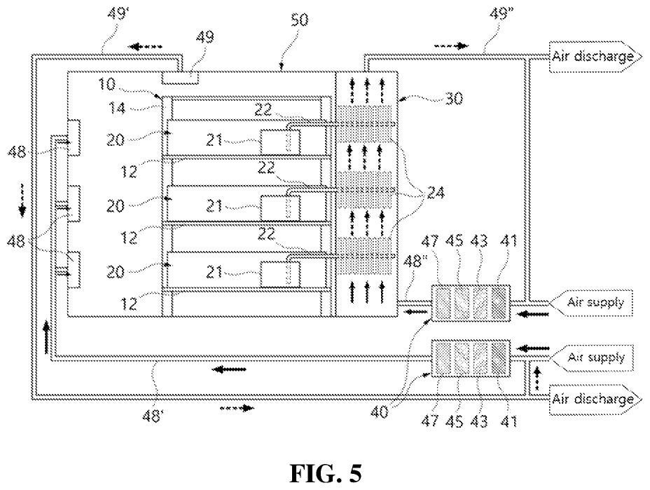

First, referring to FIG. 5, the operation of the sub-module cooling device illustrated in FIG. 2 will be described. Heat generated during the operation of the sub-module 20 may be transmitted to the heat sink 21 from the heat source. The heat transmitted to the heat sink 21 may be transmitted to the evaporation part of the first heat pipe 22 such that fluid inside the first heat pipe 22 is evaporated. The evaporated fluid inside the first heat pipe 22 may be transmitted to and be condensed at the condensation part located at the second end part of the first heat pipe 22, and thus the heat may be discharged to the outside. The heat may be transmitted to the heat radiating fins 24.

The heat radiating fins 24 may be installed in the duct 30, and thus may be in contact with air passing through the duct 30 such that the heat may be transmitted to the air. The air supplied by the air conditioner 40 may have a set temperature to receive the heat from the heat radiating fins 24. The air heat-exchanged with the heat radiating fins 24 may be discharged through the duct 30 to an air exhaust duct 49″, and thus may be discharged to the outside, or may be transmitted back to the air conditioner 40 to be used.

In the air conditioner 40, the transmitted air may pass through the filter part 41, the heating part 43, and the cooling part 45, and may have a predetermined temperature. The blowing part 47 may pressurize the air and may transmit the air to the duct 30.

Meanwhile, setting the temperature of the inside of the installation space 50 in which the sub-modules 20 are installed such that the temperature of the inside has a predetermined value may be performed in such a manner that air coming out of the separate air conditioner 40 is transmitted to the air supply diffuser 48 through the air supply duct 48′ and is supplied to the installation space 50. Of course, a separate temperature sensor may be provided and may measure the temperature in the installation space 50. On the basis of this, the temperature of the air coming out from the air conditioner 40 may be set. The air transmitted to the installation space 50 may be discharged through the air exhaust diffuser 49 located at the ceiling of the installation space 50 and may be discharged to the outside through a ventilation duct 49′ or may be transmitted back to the air conditioner 40. Such a process is indicated by arrows in FIG. 5.

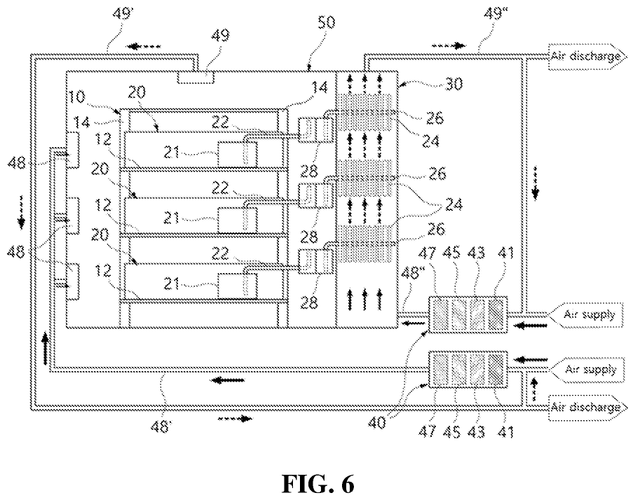

Meanwhile, in FIG. 6, the heat of the sub-module 20 according to the embodiment illustrated in FIG. 3, is illustrated to be discharged to the outside. Here, heat generated by the sub-module 20 may be transmitted to the duct 30 through the first heat pipe 22 and the second heat pipe 26. Air flowing in the duct may be in contact with and heat-exchanged with the heat radiating fins 24 located at the condensation part of the second heat pipe 26 installed in the duct 30. The connecting heat sink 28 may be located between the first heat pipe 22 and the second heat pipe 26, and thus heat discharged from the condensation part of the first heat pipe 22 may be transmitted to the evaporation part of the second heat pipe 26.

In FIG. 6, air coming out of the air conditioner 40 may pass through the duct 30 and may be transmitted to the air exhaust duct 49″ to be discharged to the outside or to flow back to the air conditioner 40. In addition, air coming out of a separate air conditioner 40 may be transmitted to the installation space 50 so as to set the temperature of the installation space 50, which is the same as the description of FIG. 3.

Meanwhile, in the embodiments illustrated in FIGS. 2 and 3, the inside of the duct 30 may be configured as illustrated in FIG. 4. That is, the paths formed in the duct 30 may be divided into paths of a number corresponding to the number of the layers of the sub-modules 20. Accordingly, when the paths 31, 32, and 33 are divided, air coming from the air conditioner 40 may be in initial contact with each of the heat radiating fins 24, so the air transmitted to all the heat radiating fins 24 may have the same temperatures. Accordingly, heat dissipation values of the heat radiating fins 24 located in the paths 31, 32, and 33, respectively, may have almost no difference.

In the above, just because all the components constituting the embodiments of the present disclosure are described as being combined integrally with each other or operating in combination, the present disclosure is not necessarily limited to these embodiments. That is, within the scope of the present disclosure, at least two of all of the components may be selectively combined with each other to be operated. In addition, the terms such as “include”, “consist of”, or “have” described above mean that corresponding components may be present unless otherwise stated, so the terms should be construed that other components may not be excluded, but further be included. All terms, including technical or scientific terms, have the same meaning as commonly understood by a person of ordinary skill in the technical field to which the present disclosure belongs, unless otherwise defined. Generally used terms, such as terms defined in a dictionary, should be interpreted as being consistent with the contextual meaning of the related technology, and should not be interpreted in an ideal meaning or an excessively formal meaning unless explicitly defined in the present disclosure.

The above description is merely illustrative of the technical idea of the present disclosure, and a person with ordinary knowledge in the technical field to which the present disclosure belongs may variously modify the embodiments within the scope of the present disclosure without departing from the essential characteristics of the present disclosure. Accordingly, the embodiments disclosed in the present disclosure are not intended to limit, but to explain the technical idea of the present disclosure, and the scope of the technical idea of the present disclosure is not limited to these embodiments. The scope of protection of the present disclosure should be interpreted by the scope of the claims below, and all technical ideas within the scope equivalent thereto should be construed as being included in the scope of the claims of the present disclosure.

In the illustrated embodiment, the duct 30 may be arranged such that air flows in a vertical direction, but may not be limited thereto. For example, the duct 30 may be installed in a horizontal direction such that air flows in the horizontal direction. However, from the point of view of natural convection, it may be more natural that the duct 30 is vertically installed to allow air to flow.

In addition, in the illustrated embodiment, the condensation part of the heat pipe 22 or 26 connected to each of the sub-modules 20 arranged on different layers of the frame 10 is configured to be located in each of the paths 31, 32, and 33 formed in the duct 30, but may not necessarily be limited thereto. The heat pipe 22 or 26 connected to each of the sub-modules 20 may be only required to be arranged in each path 31, 32, or 33 separated from each other.

In the embodiment illustrated in FIG. 3, the sub-module 20 and the duct 30 may be connected to each other by the heat pipes 22 and 26 and the connecting heat sink 28 located between the sub-module 20 and the duct 30. However, the heat pipes 22 and 26 may be provided as at least two heat pipes 22 and 26, respectively, and the connecting heat sink 28 may connect each of the heat pipes 22 and 26 to each other therebetween.

In the embodiments illustrated in FIGS. 2 and 3, the heat pipe 22 or 26 is horizontally arranged, but the heat pipe 22 or 26 may incline in direction of gravity such that fluid inside the heat pipe 22 or 26 may be efficiently recovered to the heat sink 21 and/or the connecting heat sink 28. Here, the inclination may be directed downward from the heat radiating fins 24 toward the heat sink 21 or the connecting heat sink 28.

1. A sub-module cooling device of a power transmission system, the cooling device comprising:
a frame having multiple sub-modules located on each of divided multiple layers of the frame, the sub-modules being arranged in a row on the layer;
a heat sink provided at each of the sub-modules and configured to receive heat from a heating part of the sub-module;
a heat pipe configured to receive the heat from the heat sink at an evaporation part provided at a first end part thereof and to transmit the heat to a condensation part provided at a second end part thereof;
a duct receiving the condensation part of the heat pipe therein; and
an air conditioner configured to transmit air having a predetermined temperature to the duct.

2. The cooling device of claim 1, wherein in the duct, the air flows in a vertical direction.

3. The cooling device of claim 2, wherein multiple heat radiating fins are provided at the condensation part of the heat pipe located in the duct.

4. The cooling device of claim 3, wherein the frame in which the sub-modules are installed is arranged in a separate installation space.

5. The cooling device of claim 4, wherein air having a preset temperature is supplied to the installation space by an air conditioner.

6. The cooling device of claim 5, wherein instead of the one heat pipe, multiple heat pipes are provided between the sub-module and the duct and are connected to each other by a connecting heat sink such that heat generated by the heat sink of the sub-module is transmitted to the duct.

7. The cooling device of claim 6, wherein the multiple heat pipes inclining in directions of gravity are provided between the heat sink of the sub-module and the multiple heat radiating fins.

8. The cooling device of claim 1, wherein an insulator is provided at the heat pipe.

9. The cooling device of claim 1, wherein an inside of the duct is divided into multiple paths, and the air coming out of the air conditioner flows to each of the paths, wherein heat pipes divided as many as the number of the paths are arranged in the paths, respectively.

10. The cooling device of claim 9, wherein heat pipes connected to sub-modules arranged on one layer are arranged in one path sectioned in the duct.
